(19) United States
(12) Patent Application Publication
(10) Pub. No.: US 2007/0189067 A1
(43) Pub. Date: Aug. 16, 2007

(54) Dynamic memory

(76) Inventor: Francis Goodwin, Halfmoon, NY (US)

Correspondence Address: SLATER & MATSIL LLP, 17950 PRESTON ROAD, SUITE 1000, DALLAS, TX, 75252, US

(21) Appl. No.: 11/354,430

(22) Filed: Feb. 15, 2006

(51) Int. Cl. G11C 11/00; G11C 11/34

(52) U.S. Cl. 365/180; 365/148; 365/174

(57) ABSTRACT

Device for information storage. A preferred embodiment comprises a memory with a plurality of memory cells, with each memory cell comprising a thyristor. The thyristor has three terminals: an anode terminal coupled to a first power rail, a cathode terminal coupled to a second power rail, and a gate terminal coupled to a sense device configured to detect a state of the thyristor. The use of a thyristor enables a scaling that is consistent with the scaling of other circuitry in the memory and permits the creation of denser memories. Furthermore, once a thyristor assumes a state (either on or off), the state is self-sustaining, and therefore does not require refreshing as does a memory utilizing capacitors. Additionally, it is possible to perform a non-destructive detection of the state of the thyristor.

### TECHNICAL FIELD

The present invention relates generally to a device and a method for information storage, and more particularly to a device and a method for dynamic information storage.

### BACKGROUND

The continued increase in density of dynamic memory (dynamic random access memory (DRAM)) in computer systems has enabled a corresponding increase in the capability of computer systems and other electronic devices. With denser DRAM, computers and electronic devices can offer more memory capacity without requiring an increase in the physical space devoted to the memory modules. More memory capacity can permit larger and more complex computer applications to be loaded into the computer systems, larger data files can be manipulated in memory, and so forth. Since DRAM is normally several orders of magnitude faster than secondary and tertiary memory (hard drives, tape drives, and so on), electronic devices with greater memory capacity typically provide better performance.

With reference now to FIG. 1, there is shown a diagram illustrating a prior art DRAM array. The diagram shown in FIG. 1 illustrates a standard DRAM array 100 that comprises a plurality of memory cells, such as memory cell 105, that are used to store a single bit of information. The single bit of information is stored in an electrical charge of a capacitor 110. For example, if there is more than a specified amount of electrical charge on the capacitor 110, then the memory cell 105 is considered to be storing a binary one value. The memory cell 105 is coupled to a source/drain terminal of a MOS transistor 115 that is used as a switch, with a gate terminal of the transistor 115 coupled to a word line, such as word line 120, and a drain/source terminal of the transistor 115 coupled to a bit line, such as bit line 125, of the DRAM array 100.

A row of memory cells, such as a row of memory cells containing memory cell 105, can be activated by changing a voltage on a word line, such as the word line 120, and then a particular memory cell in the row of memory cells can be stored by applying a voltage to a bit line, such as the bit line 125, associated with the memory cell. The information stored in a memory cell, such as the capacitor 110 of the memory cell 105, can be determined by sensing the electrical charge stored in the capacitor 110 with a sense amplifier 130 via the bit line 125. The sense amplifier 130 in a typical DRAM array is a differential mode amplifier and therefore, the bit line 125 may represent two conductors, with each conductor conducting one of the two signals making up the differential mode signal required by the differential mode sense amplifier 130. The determination of the information stored in the capacitor 110 is a destructive operation and after a determination of the information stored in the capacitor 110, the electrical charge of the capacitor 110 must be restored by writing the information back to the capacitor 110. Furthermore, the electrical charge of the capacitor 110 will discharge over time and the electrical charge of the capacitor 110 requires periodic refreshing.

One disadvantage of the prior art is that although the density of the DRAM array 100 can be accomplished by scaling down the size of the transistors and capacitors in the DRAM array 100, a scaled down capacitor, such as capacitor 110, will have a reduced ability to store electrical charge due to decreased capacitance. Unfortunately, larger arrays, facilitated by decreasing device size, require increased capacitance to overcome increased memory cell capacitance, bit line capacitance, parasitic capacitance, and so forth. Therefore, in large DRAM arrays, the electrical charge stored in the capacitor, and hence, the voltage on the bit line, would become so low that it would be difficult to determine a state of the information stored in the capacitor.

### SUMMARY OF THE INVENTION

These and other problems are generally solved or circumvented, and technical advantages are generally achieved, by preferred embodiments of the present invention which provides a device and a method for dynamic information storage.

In accordance with a preferred embodiment of the present invention, a dynamic memory is provided. The dynamic memory includes a multitude of memory cells, with each memory cell including a thyristor. The thyristor has three terminals: an anode terminal, a cathode terminal, and a gate terminal, with the anode terminal being coupled to a first power rail, and the cathode terminal being coupled to a second power rail. The gate terminal is coupled to a sense amplifier that is used to detect the state of the thyristor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram of a prior art dynamic memory array;

FIGS. 2a and 2b are diagrams of a physical structure of a gate turn-off thyristor and a circuit model of a gate turn-off thyristor;

FIGS. 3a through 3c are diagrams of current flow through a gate turn-off thyristor;

FIGS. 4a and 4b are diagrams of current flow through a gate turn-off thyristor in a turn ON mode and a turn OFF mode, according to a preferred embodiment of the present invention;

FIG. 5 is a diagram of a dynamic memory array, wherein gate turn-off thyristors are used as memory cells, according to a preferred embodiment of the present invention;

FIGS. 6a through 6c are diagrams of circuit models of exemplary thyristors that can be used as memory cells, according to a preferred embodiment of the present invention;

FIG. 7 is a diagram of a physical structure of an exemplary thyristor memory cell, according to a preferred embodiment of the present invention; and

FIGS. 8a through 8d are diagrams of sequences of events in the determination of memory cell state and setting memory cell state, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a dynamic random access memory (DRAM) array with a gate-controlled switch employed as memory cell that can be scaled on the order of support circuitry, such as transistors used as switches and sense amplifiers, to facilitate the continued increase in the density of the DRAM array, with the memory cell being a gate turn-off (GTO) thyristor. However, the present invention can be applied to other types of thyristors, such as a MOS-controlled thyristor (MCT), a MOS-gated thyristor, a field-controlled thyristor (FCT), an emitter-switched thyristor (EST), an insulated gate turn-off thyristor (IGTT), an insulated gate thyristor (IGT), a gate-commutated thyristor (GCT), an integrated gate-command thyristor (IGCT), a base resistance controlled thyristor (BRT), and so forth.

A thyristor is a solid-state semiconductor device that is similar to a diode. However, a thyristor has an additional control terminal, a gate terminal, that can be used to control the conduction of the thyristor. A thyristor will turn one when a current is provided at the gate terminal and once the thyristor is turned on, the thyristor will remain in the on state as long as it remains forward biased. Thyristors are considered to be well understood by those of ordinary skill in the art of the present invention.

With reference now to FIGS. 2a and 2b, there are shown diagrams illustrating a physical structure of a GTO 200 and an equivalent circuit model of the GTO 200. The diagram shown in FIG. 2a illustrates the structure of the GTO 200. The GTO 200 includes three terminals (an anode terminal, a cathode terminal, and a gate terminal) and four different layers of semiconductor material. Starting at the anode terminal, a first layer 205 can be made from a first P-doped semiconductor material. Adjacent to the first layer 205 is a second layer 210 made from a first N-doped semiconductor material. Completing the GTO 200 is a third layer 215 made from a second P-doped semiconductor material and a fourth layer 220 made from a second N-doped semiconductor material. The cathode terminal is coupled to the fourth layer 220 while the gate terminal is coupled to the third layer 215.

Dopant concentration of the first layer 205, the second layer 210, the third layer 215, and the fourth layer 220 can differ depending upon desired performance characteristics of the GTO 200. For example, the dopant concentration of the first layer 205 can be greater than the dopant concentration of the third layer 215 and the dopant concentration of the second layer 210 can be less than the dopant concentration of the fourth layer 220. A junction J1 is formed between the first layer 205 and the second layer 210, a junction J2 is formed between the second layer 210 and the third layer 215, and a junction J3 is formed between the third layer 215 and the fourth layer 220.

The diagram shown in FIG. 2b illustrates an equivalent circuit model 260 of the GTO 200. The first layer 205, the second layer 210, and the third layer 215 form a PNP transistor, shown as a PNP transistor 265, while the second layer 210, the third layer 215, and the fourth layer 220 form a NPN transistor, shown as an NPN transistor 270. The anode terminal of the GTO 200 is coupled to an emitter terminal of the PNP transistor 265 and the cathode terminal of the GTO 200 is coupled to an emitter terminal of the NPN transistor 270. The PNP transistor 265 and the NPN transistor 270 are cross coupled, with a collector terminal of the PNP transistor 265 and a base terminal of the NPN transistor 270 while a base terminal of the PNP transistor 265 is coupled to a collector terminal of the NPN transistor 270. The base terminal of the GTO 200 is also coupled to the collector terminal of the PNP transistor 265 and the base terminal of the NPN transistor 270.

With reference now to FIGS. 3a through 3c, there are shown diagrams illustrating a GTO 200 turn ON sequence. The GTO 200 can have two stable states, an ON state and an OFF state. The state of the GTO 200 is determined by a current (I_{G}) provided via the gate terminal of the GTO 200. When the current (I_{G}) is injected into the GTO 200 from the gate terminal to the cathode terminal (FIG. 3a), the NPN transistor 270 is turned ON and a collector current (IcNpN) through the NPN transistor 270 will flow from the anode terminal of the GTO 200 through the junction J1 (FIG. 3b). Since the junction J1 is the emitter junction of the PNP transistor 265, the collector current (ICPNP) of the PNP transistor 265 is the base current of the NPN transistor 270 (FIG. 3c).

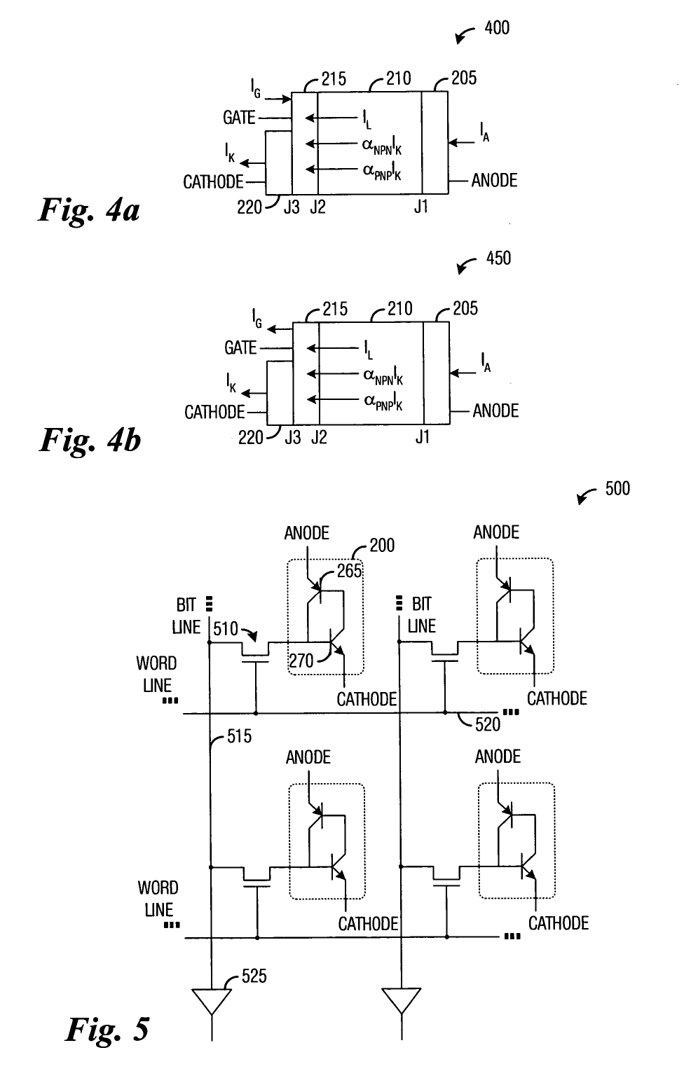

With reference now to FIG. 4a, there is shown a diagram illustrating a model 400 illustrating current flow in the GTO 200 in a turn ON mode, according to a preferred embodiment of the present invention. The turning ON of the junction J3 (between the third layer 215 and the fourth layer 220) results in the injection of electrons into the base of the NPN transistor 270 (the third layer 215). The electrons also diffuse across the third layer 215 and are mostly collected by the junction J2, a reverse biased junction. In order to maintain the continuity of the current, the junction J I will supply a current by injecting holes into the second layer 210, which are collected by the junction J2. The current from the injected holes results in the injection of additional electrons from the junction J3. When both transistors (the PNP transistor 265 and the NPN transistor 270) operate with sufficient current gain, a positive feedback mechanism is adequate to result in latch-up.

If the common base current gain of the PNP transistor 265 is α_{PNP} and the NPN transistor 270 is α_{NPN}, with α_{PNP} typically being smaller than ANPN since the PNP transistor 265 is a wide base structure, then the current flow inside the GTO 200 is expressible as:
I_{K}=α_{PNP}I_{A}+α_{NPN}I_{K}+I_{L}
I_{A}=I_{K}−I_{G}
where, I_{A} is the anode current, I_{K} is the cathode current, I_{L} is the leakage current, and I_{G} is the gate current. Combining the two equations,

I_{A}=α_{PNP}I_{G}+I_{L})/(1−α_{PNP}−α_{NPN}). As the sum of the two transistors' common base current gain (α_{PNP}+α_{NPN}) approaches unity, the GTO 200 can self-sustain its anode current. Therefore, once the GTO 200 is turned ON, additional current through the gate terminal is no longer needed.

With reference now to FIG. 4b, there is shown a diagram illustrating a model 450 illustrating current flow in the GTO 200 in a turn OFF mode, according to a preferred embodiment of the present invention. When the gate is pulling current from the GTO 200, the current injection into the base (the third layer 215) of the NPN transistor 270 will be reduced. Once the current injection is reduced to below a certain level, the collector current of the NPN transistor 270 and the base current of the PNP transistor 265 will also decrease. This will lead to a reduced collector current of the PNP transistor 265. This will further reduce the base current of the NPN transistor 270 since the base current of the NPN transistor 270 is a difference of the collector current of the PNP transistor 265 and the gate current. The model 450 shown in FIG. 5 illustrates the currents described above.

The base current required to maintain current conduction in the NPN transistor 270 is (1−α_{NPN})I_{K}. and the base current that is available to the NPN transistor 270 is (α_{PNP}I_{A}−I_{G}). Therefore, to turn OFF the GTO 200 via the gate current control, the following condition must be met:
α_{PNP}I_{A}−I_{G}<(1−α_{NPN})I_{K}.
Since I_{K}=I_{A}−I_{G}, the condition to turn OFF the GTO 200 is expressible as:

$${I}_{G} > \frac{( {α}_{PNP} + {α}_{NPN} - 1 )}{{α}_{NPN}} {I}_{A} .$$

The above condition for I_{G} can be used to express a maximum turn OFF gain (βₘ), a ratio of the anode current to the gate current at a level that would turn OFF the GTO 200. The maximum turn OFF gain can be expressed as:

$${β}_{m} ≡ \frac{{I}_{A}}{{I}_{G}} = \frac{{α}_{NPN}}{{α}_{PNP} + {α}_{NPN} - 1} .$$

Typically, the GTO 200 is designed with a turn OFF gain (μₘ) of three to five.

To turn OFF the GTO 200, a negative turn OFF voltage is applied to the GTO's gate-cathode junction. The current that was originally flowing through the cathode will then be diverted to the gate, causing the cathode current (I_{K}) to decrease and the gate current (I_{G}) to increase. With a larger gate current (I_{G}), a time required to remove minority carriers in the base of the NPN transistor 270 is decreased. If the gate current (I_{G}) is much less than the anode current (I_{A}), then the minority carrier removal rate is low and the GTO 200 stays ON for a longer time.

If the gate current (I_{G}) is maintained at a level that is much less than the anode current (I_{A}) and if the gate current (I_{G}) is maintained so that the condition

$${I}_{G} > \frac{( {α}_{PNP} + {α}_{NPN} - 1 )}{{α}_{NPN}} {I}_{A}$$

is maintained, the GTO 200 that is already ON can be sampled without turning it OFF. Therefore, the information stored in the GTO 200 can be determined without requiring a change in the state of the GTO 200.

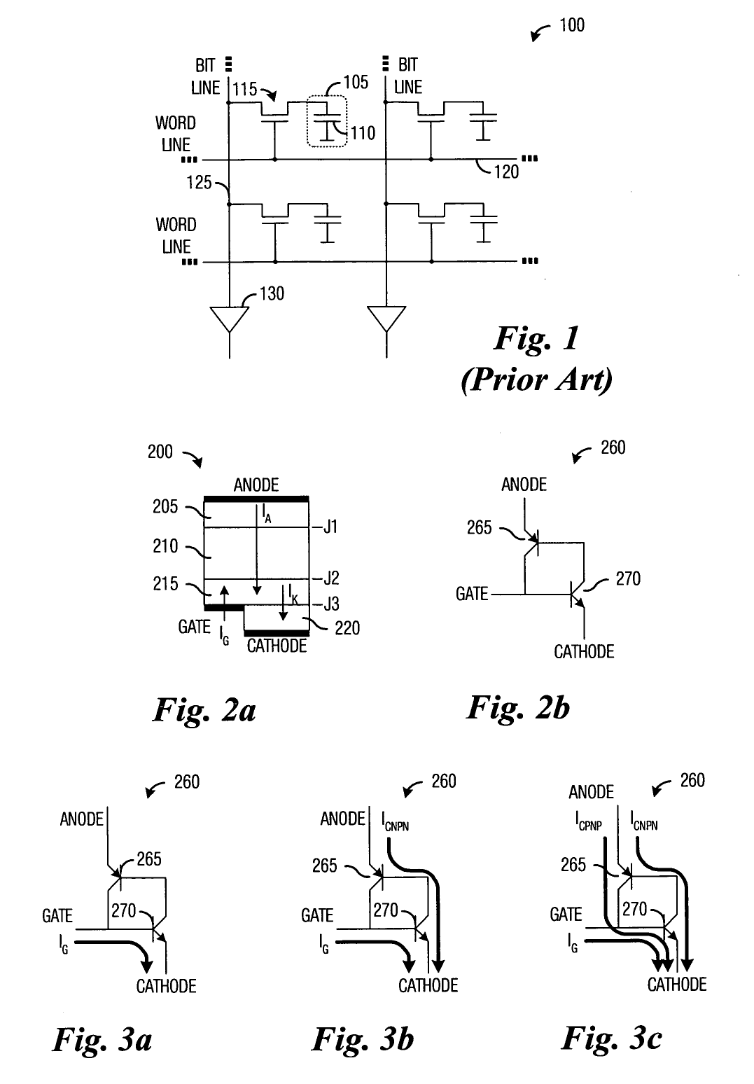

With reference now to FIG. 5, there is shown a diagram illustrating a DRAM array 500, wherein memory cells in the DRAM array 500 are GTO thyristors, according to a preferred embodiment of the present invention. The DRAM array 500 features GTO thyristors (GTO) 200 in place of capacitors (such as memory cell 105 (FIG. 1)) as memory cells. Although the diagram shown in FIG. 500 illustrates the use of GTO thyristors as memory cells, other thyristors (such as MOS-controlled thyristors (MCT), MOS-gated thyristors, field-controlled thyristors (FCT), emitter-switched thyristors (EST), insulated gate turn-off thyristors (IGTT), insulated gate thyristors (IGT), gate-commutated thyristors (GCT), integrated gate-command thyristors (IGCT), and so forth) can be used as memory cells.

The anode and the cathode of the GTO 200 can be coupled to power supply rails and the gate of the GTO 200 can be coupled to a switch transistor 510 that can be used to control the coupling of the GTO 200 to a bit line, such as bit line 515. A gate terminal of the switch transistor 510 can be coupled to a word line, such as word line 520. The combination of a word line and a bit line can enable the writing of information to the GTO 200 as well as a detection of the information already in the GTO 200. A sense amplifier, such as sense amplifier 525, can detect the information stored in the GTO 200 by detecting a change in a current on a bit line, such as bit line 515. If there is a change in the bit line current, then the GTO 200 is determined to be in an on state and if there is no change in the bit line current, then the GTO 200 is determined to be in an off state. As with a standard DRAM, the sense amplifier 525 may be a differential mode amplifier.

For example, to write a value to the GTO 200, a voltage would be applied to the bit line 515 and the word line 520 associated with the GTO 200. The voltage would provide the gate current (I_{G}) needed to turn ON the GTO 200. Once turned on, the current in the GTO 200 would be self-sustaining and the gate current (I_{G}) is no longer needed to control the state of the GTO 200. To determine the state of the GTO 200, and therefore, the information stored in the GTO 200, the word line 520 is positively biased with respect to the cathode of the GTO 200 and if the GTO 200 is ON, a current will be present on the bit line 515 that would be detected by the sense amplifier 525. If the GTO 200 is OFF, then no current will be present on the bit line 515 and the sense amplifier 525 would not be able to detect a current on the bit line 515.

It is possible to reverse bias the anode to allow the minority carriers in the GTO 200 to be removed from both the anode and the cathode of the GTO 200. This will permit the GTO 200 to more rapidly switch from an ON state to an OFF state since the anode will also be usable to remove the minority carriers in the GTO 200, while if the anode is not reverse biased, only the cathode of the GTO 200 will be usable for removing the minority carriers in the GTO 200.

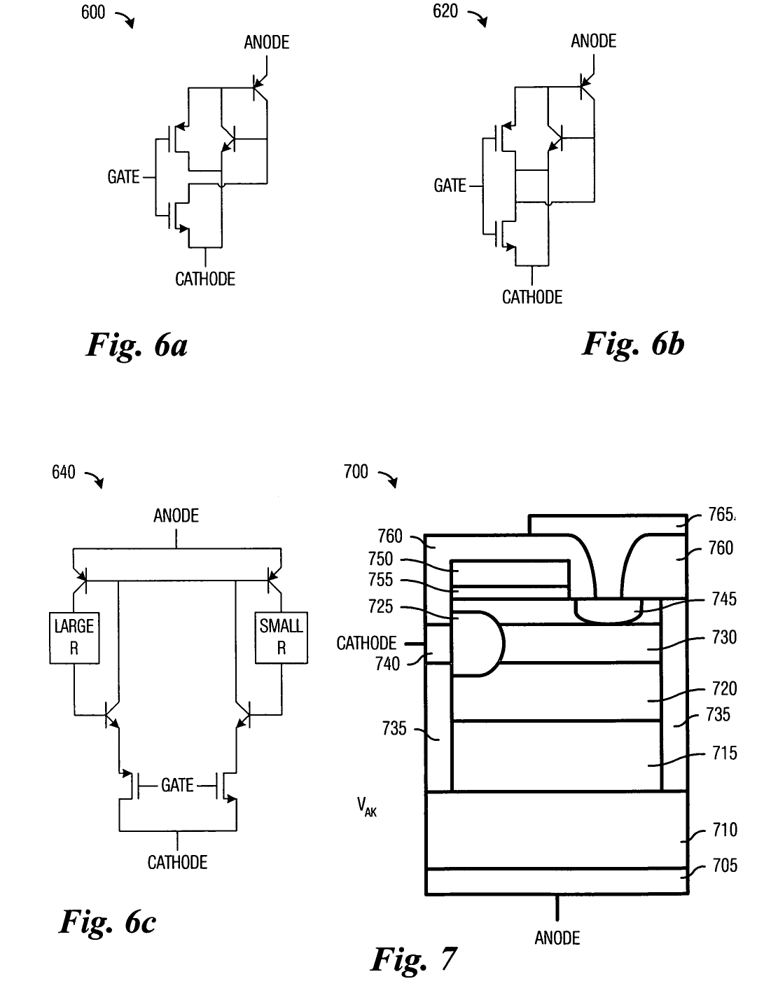

With reference now to FIGS. 6a through 6c, there are shown diagrams illustrating exemplary thyristors that can be used as memory cells, according to a preferred embodiment of the present invention. The diagrams shown in FIGS. 6a through 6c illustrate several exemplary thyristors that can be used as memory cells, such as a MOS-controlled thyristor (MCT) 600 (FIG. 6a), a base resistance controlled thyristor (BRT) 620 (FIG. 6b), and an emitter-switched thyristor (EST) 640 (FIG. 6c). The diagrams shown in FIGS. 6a through 6c are intended to illustrate several thyristors that can be used as memory cells, in addition to the gate turn-off thyristor discussed previously. The diagrams are not intended to be an exhaustive illustration of viable thyristors that can be used as memory cells.

With reference now to FIG. 7, there is shown a diagram illustrating an exemplary thyristor memory cell 700, according to a preferred embodiment of the present invention. A plating 705 functions as an anode contact on a P+ doped substrate 710 (layer 205 in FIG. 2a), with the P+ doped substrate 710 forming a first layer of the thyristor memory cell 700 (a GTO thyristor). While an N− doped layer 715 (layer 210 in FIG. 2a), a P doped layer 720 (layer 215 in FIG. 2a), and an N+ doped region 725 (layer 220 in FIG. 2a) form the remaining three layers of the thyristor memory cell 700. A P+ isolation region 730 can be used later in the formation of a switch transistor (such as the switch transistor 510), while a dielectric layer 735 filling trenches can function as isolators for the thyristor memory cell 700. A contact 740 is formed for use as the cathode terminal of the thyristor memory cell 700. An N+ contact area 745 can then implanted while a gate region is created with a poly gate 750 and a gate insulator 755, forming the switch transistor, with the N+ doped region 725 and the N+ contact area 745 forming the drain/source regions of the switch transistor. The poly gate 750 can also be used as the word line of the memory cell. Additional dielectric material 760, which can be deposited or grown, can form a passivation layer over the thyristor memory cell 700 and a contact 765 forms the gate terminal of the thyristor memory cell 700.

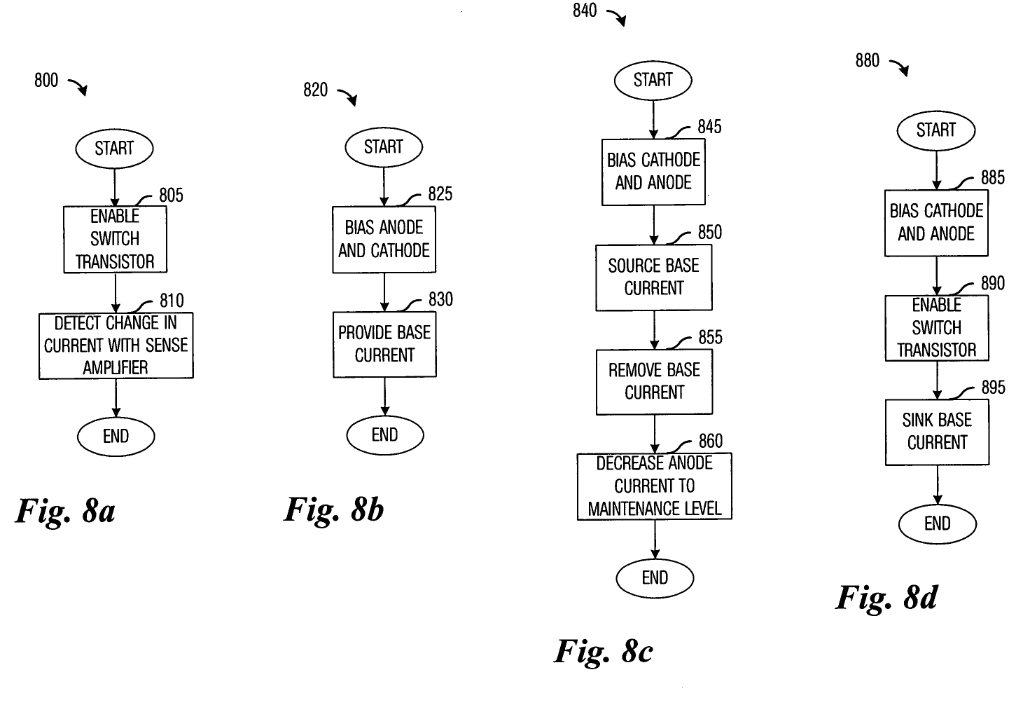

With reference now to FIGS. 8a through 8d, there are shown diagrams illustrating sequences of events in the accessing of a memory cell of a memory array, wherein the memory cell comprises a thyristor, according to a preferred embodiment of the present invention. Access to a thyristor memory cell includes retrieving a stored value in the thyristor memory cell and storing a value to the thyristor memory cell. A sequence of events 800 shown in FIG. 8a illustrates the retrieving (reading) of the stored value in the thyristor memory cell. In order to retrieve the stored value in the thyristor memory cell, a switch transistor can first be enabled (block 805) to provide a current path from the thyristor memory cell to a sense amplifier. The enabling of the switch transistor can be achieved by biasing the word line of the thyristor memory cell so that a current path is created under the poly gate 750 and the gate insulator 755. The stored value in the thyristor memory cell can then be determined by detecting a change in a current seen at the base terminal of the thyristor memory cell (block 810). If there is a change in the current, then the stored value is determined to be an active value, i.e., the thyristor memory cell is in an on state. If there is not a change in the current, then the stored value is determined to be an inactive value, i.e., the thyristor memory cell is in an off state.

A sequence of events 820 shown in FIG. 8b illustrates the events in the storing of a value to the thyristor memory cell. Before a value can be stored to the thyristor memory cell, the biasing of the anode terminal and the cathode terminal of the thyristor memory cell needs to be properly adjusted so that the thyristor memory cell can be in a proper operating mode (block 825). Once placed in a proper operating mode, a base current of a specified magnitude and polarity can be provided to either turn the thyristor memory cell on or off (block 830).

The diagram shown in FIG. 8c illustrates a detailed sequence of events 840 in the storing of an active value in the thyristor memory cell, i.e., turning the thyristor memory cell on. To begin turning on the thyristor memory cell, the anode terminal and the cathode terminal of the thyristor memory cell must be properly biased (block 845). According to a preferred embodiment of the present invention, the cathode terminal is biased negative with respect to the anode terminal. A base current of specified magnitude can then be provided to the thyristor memory cell (block 850). The base current can be maintained until a resulting anode current is large enough to turn on the thyristor memory cell. The base current can then be removed (block 855) and the anode current can be decreased to a maintenance level (block 860).

The diagram shown in FIG. 8d illustrates a detailed sequence of events 880 in the storing of an inactive value in the thyristor memory cell, i.e., turning the thyristor memory cell off. To turn off the thyristor memory cell, the anode terminal and the cathode terminal of the thyristor memory cell must be properly biased (block 885). According to a preferred embodiment of the present invention, the bias between the anode terminal and the cathode terminal of the thyristor can be brought down to zero to properly bias the thyristor memory cell for turning off. Then, the word line of the thyristor memory cell is biased so that a conducting channel is formed under the switch transistor (block 890). Then, a base current is sinked by the bit line of the thyristor memory cell (block 895) to deplete charge carriers from the thyristor memory cell, turning the thyristor memory cell off.

In accordance with another preferred embodiment of the present invention, a method for setting a memory cell to a desired state is provided. The memory cell includes a thyristor having three terminals: an anode terminal, a cathode terminal, and a gate terminal. The method includes applying a voltage bias to the anode terminal and the cathode terminal of the memory cell and providing a base current to the base terminal of the memory cell, where the magnitude and the polarity of the base current is dependent on the desired state.

In accordance with another preferred embodiment of the present invention, a method for reading a state of a memory cell is provided. The memory cell includes a thyristor having three terminals: an anode terminal, a cathode terminal, and a gate terminal. The method includes enabling a switch transistor that is coupled between the base terminal and a memory detect line determining a state of the memory cell in response to a sensed current at the switch transistor.

In accordance with another preferred embodiment of the present invention, a dynamic memory is provided. The dynamic memory includes a plurality of memory units, a plurality of memory unit select lines, and a plurality of memory unit detect/set lines. Each memory unit includes a thyristor having an anode terminal, a cathode terminal, and a gate terminal, the thyristor to store information. Each memory unit also includes a switch coupled to the gate terminal, the switch to enable the detecting of the state of the thyristor or a setting of the state of the thyristor. Each memory unit select line is coupled to a switch enable of the switch in each memory unit of a subset of memory units with one subset of memory units for each memory unit select line and each memory unit detect/set line is coupled to a switch of a single memory unit in each subset of memory units to a sense amplifier with the sense amplifier detecting the state of the memory unit by detecting a current on the memory unit detect/set line.

An advantage of a preferred embodiment of the present invention is that the GTO (and other forms of thyristors) contain transistors that are fabricated using standard semiconductor device fabrication processes. The fabrication of the transistors can be performed with less expense that the fabrication of capacitors. Therefore, the cost of the DRAM arrays using the GTO can be significantly cheaper than DRAM arrays using capacitors.

A further advantage of a preferred embodiment of the present invention is that the size of the transistors used in the GTO (and other forms of thyristors) can be scaled along with the other circuitry (such as the switch transistors and sense amplifiers) in the DRAM array. The ability to reduce the size of the GTO at a rate that is similar to the reduction of the size of the other circuitry in the DRAM array can allow for denser DRAM arrays, which can lead to larger capacity memory chips while maintaining a consistent physical size.

Yet another advantage of a preferred embodiment of the present invention is that the GTO (and other forms of thyristors) can self-sustain their state. Therefore, once a value is stored in the GTO, the GTO does not need to be periodically refreshed as is the case of the capacitor memory cell. Furthermore, the state of the GTO can be determined without requiring a destructive detection or reading of the state of the GTO, therefore, the state of the GTO does not have to be rewritten after the state of the GTO is detected or read.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A memory having a plurality of memory cells, each memory cell comprising a thyristor, the thyristor having an anode terminal, a cathode terminal, and a gate terminal, and wherein the anode terminal is coupled to a first power rail, the cathode terminal is coupled to a second power rail, and the gate terminal is coupled to a sense device configured to detect a state of the thyristor.

2. The memory of claim 1, wherein each memory cell comprises a gate turn-off thyristor.

3. The memory of claim 2, wherein each memory cell comprises:
a first semi-conductive layer coupled to the anode terminal;
a second semi-conductive layer adjacent to the first semi-conductive layer;
a third semi-conductive layer adjacent to the second semi-conductive layer, the third semi-conductive layer coupled to the gate terminal; and
a fourth semi-conductive layer adjacent to the third semi-conductive layer, the fourth semi-conductive layer coupled to the cathode terminal.

4. The memory of claim 3, wherein the first semi-conductive layer and the third semi-conductive layer are formed from P-doped materials and the second semi-conductive layer and the fourth semi-conductive layer are formed from N-doped materials.

5. The memory of claim 2, wherein a magnitude and a polarity of a current provided at the gate terminal of the thyristor is used to set a state of the memory cell.

6. The memory of claim 2 further comprising:
a fifth semi-conductive layer adjacent to the fourth semi-conductive layer and the third semi-conductive layer, the fifth semi-conductive layer containing a buried implant region, wherein the buried implant region is positioned between the third semi-conductive layer and the gate terminal; and
an insulator layer adjacent to the fifth semi-conductive layer, the insulator layer insulating the fifth semi-conductive layer from a sixth semi-conductive layer.

7. The memory of claim 1, wherein each memory cell comprises a thyristor selected from a group consisting of gate turn-off thyristors (GTO), MO S-controlled thyristors (MCT), MOS-gated thyristors, field-controlled thyristors (FCT), emitter-switched thyristors (EST), insulated gate turn-off thyristors (IGTT), insulated gate thyristors (IGT), gate-commutated thyristors (GCT), and integrated gate-command thyristors (IGCT).

8. A method for setting a memory cell to a desired state, wherein the memory cell comprises a thyristor, wherein the thyristor comprises an anode terminal, a cathode terminal, and a gate terminal, the method comprising:
applying a voltage bias on the anode terminal and the cathode terminal of the memory cell; and
providing a base current to the base terminal of the memory cell, wherein a magnitude and a polarity of the base current is dependent upon the desired state.

9. The method of claim 8, wherein the desired state is an on state, wherein the providing comprises sourcing a base current with a desired magnitude to create an anode current to turn on the memory cell, and the method further comprising:
stopping the base current after the memory cell has turned on; and
reducing the anode current to a maintenance level.

10. The method of claim 9, wherein the applying comprises setting the voltage bias so that the cathode terminal is negatively biased with respect to the anode terminal.

11. The method of claim 8, wherein the desired state is an off state, and the method further comprising after the applying, enabling a switch transistor coupled between the base terminal and a power rail, the switch transistor electrically couples the base terminal to the power rail.

12. The method of claim 11, wherein the providing a base current comprises sinking the base current to the power rail.

13. The method of claim 11, wherein the applying comprises setting the voltage bias to be substantially equal to zero.

14. A method for reading a state of a memory cell, wherein the memory cell comprises a thyristor, wherein the thyristor comprises an anode terminal, a cathode terminal, and a gate terminal, the method comprising:
enabling a switch transistor coupled between the base terminal and a memory detect line; and
determining the state of the memory cell in response to a sensed current at the switch transistor.

15. The method of claim 14, wherein the state of the memory cell is on in response to a determination that there is a change in the sensed current and the state of the memory cell is off in response to a determination that there is no change in the sensed current.

16. A memory comprising:
a plurality of memory units, each memory unit comprising
a thyristor to store information, the thyristor having an anode terminal, a cathode terminal, and a gate terminal, and wherein the anode terminal is coupled to a first power rail, the cathode terminal is coupled to a second power rail;
a switch coupled to the gate terminal of the thyristor, the switch configured to enable a detecting of a state of the thyristor or a setting of the state of the thyristor;
a plurality of memory unit select lines, each memory unit select line coupled to a switch enable of the switch in each memory unit of a subset of memory units, wherein there is one subset of memory units for each memory unit select line; and
a plurality of memory unit detect/set lines, each memory unit detect/set line coupled to a switch of a single memory unit in each subset of memory units to a sense device, wherein the sense device detects the state of the memory unit by detecting a current on the memory unit detect/set line.

17. The memory of claim 16, wherein the sense device is a differential mode device, and wherein each memory unit detect/set line comprises a pair of conductors.

18. The memory of claim 16, wherein the thyristor is a gate turn-off thyristor, and wherein the gate turn-off thyristor comprises:
a PNP transistor having an emitter terminal, a base terminal, and a collector terminal, wherein the emitter terminal of the PNP transistor is coupled to the anode terminal of the thyristor and the collector terminal of the PNP transistor is coupled to the base terminal of the thyristor; and
a NPN transistor having an emitter terminal, a base terminal, and a collector terminal, wherein the emitter terminal of the NPN transistor is coupled to the cathode terminal of the thyristor and the base terminal of the NPN transistor is coupled to the base terminal of the thyristor.

19. The memory of claim 18, wherein the collector terminal of the PNP transistor is coupled to the base terminal of the NPN transistor and the collector terminal of the NPN transistor is coupled to the base terminal of the PNP transistor.

20. The memory of claim 18, wherein the PNP transistor has a base current gain α_{PNP}) and the NPN transistor has a base current gain (α_{NPN}), and wherein the geometry of the PNP transistor and the NPN transistor are sized so that a sum of α_{PNP} and α_{NPN} approaches unity.
